(19) United States
(12) Patent Application Publication
(10) Pub. No.: US 2015/0255656 A1
(43) Pub. Date: Sep. 10, 2015

(54) SOLAR CELL AND SOLAR MODULE INCLUDING THE SAME

(71) Applicant: MOTECH INDUSTRIES INC., New Taipei City (TW)

(72) Inventors: Liang-Tang Wang, Tainan City (TW); Po-Tsung Hsieh, Kaohsiung City (TW)

(21) Appl. No.: 14/601,726

(22) Filed: Jan. 21, 2015

(30) Foreign Application Priority Data
Mar. 7, 2014 (TW) 103107884

(51) Int. Cl. H01L 31/056; H01L 31/048; H01L 31/0216

(52) U.S. Cl. CPC H01L 31/056; H01L 31/02167; H01L 31/02168; H01L 31/048

(57) ABSTRACT

A solar cell includes a substrate having an incident surface and a back surface, an emitter layer formed on the incident surface, an anti-reflective layer formed on the emitter layer opposite to the substrate, a passivation unit formed on the back surface of the substrate, a plurality of metallic nanoparticles capable of reflecting light and disposed in the passivation unit, a first electrode disposed on and electrically connected to the emitter layer, and a second electrode disposed on the passivation unit and electrically connected to the substrate. A solar module including the aforesaid solar cell is also disclosed.

### CROSS-REFERENCE TO RELATED APPLICATION

This application claims priority of Taiwanese application no. 103107884, filed on Mar. 7, 2014.

### BACKGROUND OF THE INVENTION

1. Field of the Invention

This invention relates to a solar cell and a solar module including the same.

2. Description of the Related Art

A conventional solar cell includes a substrate capable of converting light energy into electrical energy, an anti-reflective layer formed on a light incident surface of the substrate, and an electrode pair disposed on the substrate and capable of transferring the electrical energy generated by the substrate outwardly.

Currently, there are mainly two methods to increase short circuit current (Isc) of the solar cell: (1) increasing the amount of light entering the substrate, and (2) decreasing the amount of light passing through and unused by the substrate. Through these two methods, the amount of light inside the substrate is increased so as to enhance the light absorption of the solar cell.

For the abovementioned method (1), changing the structure of the substrate is a common way to increase the amount of light entering the substrate. This can be done by roughening the light incident surface of the substrate and by coating an anti-reflective layer on the light incident surface. With these structures, the amount of the incident light entering the substrate can be increased, thereby improving the efficiency of the solar cell.

For the abovementioned method (2), the solar cell is typically made from a crystalline silicon substrate which has a better absorption of light with shorter wavelength than that of longer wavelength. Therefore, when light enters into the crystalline silicon substrate, the light with shorter wavelength will be absorbed by the substrate and converted into the electrical energy. The light with longer wavelength usually is not effectively absorbed and thus leaves the substrate. If the reflection, refraction, and diffraction of the light with longer wavelength can be enhanced in the substrate to allow more chances of absorption of the light, the efficiency of photovoltaic conversion of the solar cell may be improved.

### SUMMARY OF THE INVENTION

Therefore, the object of the present invention is to provide a solar cell and a solar module that can overcome the aforesaid drawback of the prior art.

According to one aspect of this invention, a solar cell comprises:

a substrate of a first conductivity type, the substrate having an incident surface and a back surface opposite to the incident surface;

an emitter layer that is formed on the incident surface of the substrate and that has a second conductivity type different from the first conductivity type of the substrate;

an anti-reflective layer formed on the emitter layer opposite to the substrate;

a passivation unit that is formed on the back surface of the substrate;

a plurality of metallic nanoparticles that are capable of reflecting light and that are disposed in the passivation unit;

a first electrode disposed on and electrically connected to the emitter layer; and

a second electrode disposed on the passivation unit and electrically connected to the substrate.

According to another aspect of this invention, a solar module comprises:

a first base plate;

a second base plate;

the aforesaid solar cell of this invention that is disposed between the first base plate and the second base plate; and

an encapsulant that is disposed between the first base plate and the second base plate and that encapsulates the solar cell.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a fragmentary and partly cross-sectional view of the preferred embodiment of a solar module according to the present invention;

FIG. 2 is a partly cross-sectional view of a solar cell included in the preferred embodiment of the solar module; and

FIG. 3 is a fragmentary cross-sectional view of a variant of the solar cell shown in FIG. 2.

### DETAILED DESCRIPTION OF THE PREFERRED EMBODIMENT

Before the present invention is described in greater detail, it should be noted that like elements are denoted by the same reference numerals throughout the disclosure.

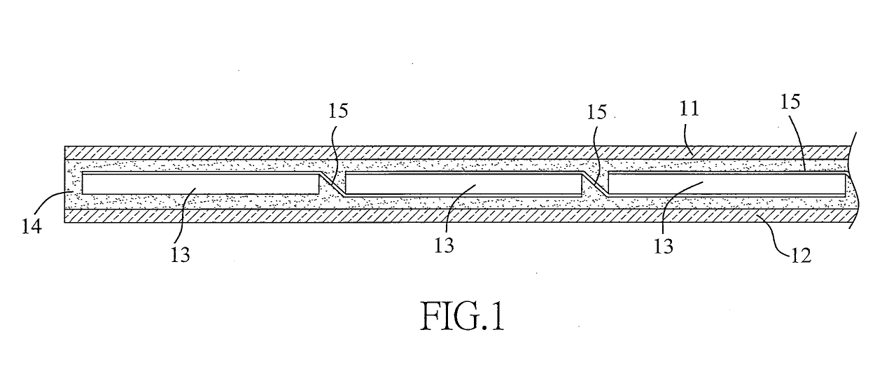

Referring to FIG. 1, the preferred embodiment of a solar module according to the present invention is shown to include a first base plate 11, a second base plate 12, multiple solar cells 13 arranged between the first base plate 11 and the second base plate 12, and an encapsulant 14 that is disposed between the first base plate 11 and the second base plate 12 and that encapsulates the solar cells 13.

In this embodiment, the first base plate 11 and the second base plate 12 are made from a light-transmissible material, such as, but not limited to, glass or plastic material. The solar cells 13 are electrically connected through conductor ribbons 15. The encapsulant 14 is made from ethylene-vinylacetate copolymer (EVA) or other encapsulant materials suitable for packaging solar cells. Because the structures of the solar cells 13 are the same, only one solar cell will be described below. However, it is not essential for the structures of the multiple solar cells 13 in a solar module to be the same.

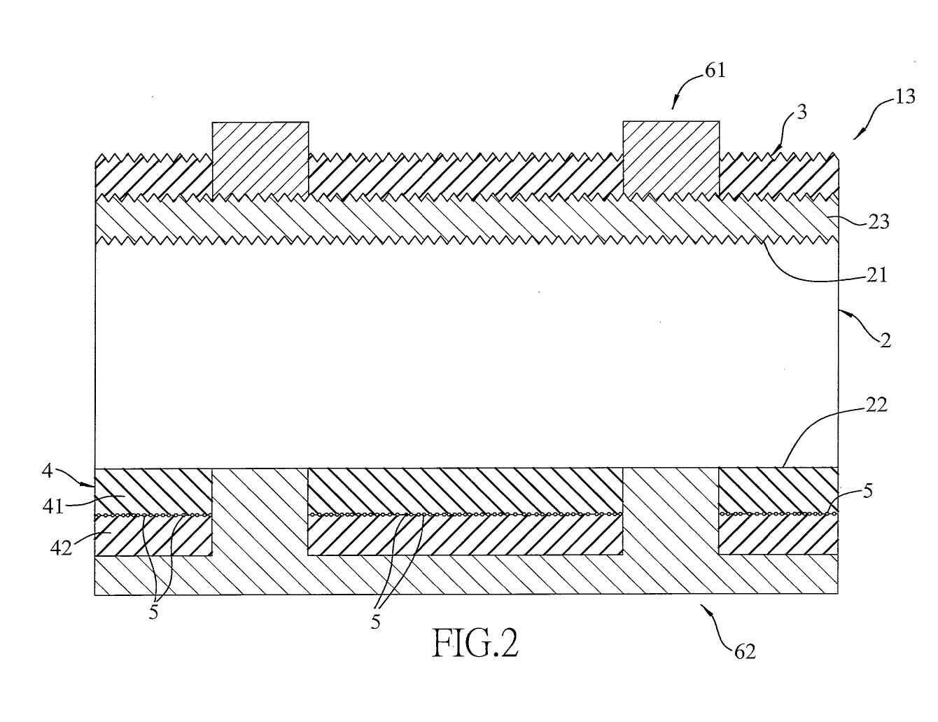

Referring to FIG. 2, the solar cell 13 includes a substrate 2, an emitter layer 23, an anti-reflective layer 3, a passivation unit 4, a plurality of metallic nanoparticles 5, a first electrode 61, and a second electrode 62. In this embodiment, the solar cell 13 is a passivated emitter and rear contact (PERC) type solar cell.

The substrate 2 is of a first conductivity type and has an incident surface 21 and a back surface 22 opposite to the incident surface 21.

In this embodiment, the substrate 2 is a p-type crystalline silicon substrate and made of mono-or poly-crystalline silicon. The incident surface 21 has a roughened structure which decreases the reflection of incident light.

The emitter layer 23 is formed on the incident surface 11 of the substrate 2 and has a second conductivity type (i.e. n-type in this embodiment) that is different from the first conductivity type of the substrate 2. The emitter layer 23 forms a p-n junction with the substrate 2 and has a roughened structure corresponding to that of the incident surface 21 of the substrate 2.

In this embodiment, the anti-reflective layer 3 is formed on the emitter layer 23 opposite to the substrate 2 and has a roughened structure corresponding to that of the emitter layer 23. The material, such as silicon nitride (SiNₓ), for the anti-reflective layer 3 is capable of increasing the incident light entering the substrate 2 and decreasing the surface recombination velocity (SRV) of carriers.

In this embodiment, the passivation unit 4 is formed on the back surface 22 of the substrate 2, and includes a first passivation layer 41 formed on the back surface 22 of the substrate 2, and a second passivation layer 42 formed on the first passivation layer 41 opposite to the substrate 2. The passivation unit 4 is used to repair and reduce the surface or internal defects of the substrate as well as to decrease the surface recombination velocity (SRV) of carriers in order to improve the efficiency of photovoltaic conversion.

The first passivation layer 41 and the second passivation layer 42 are independently made from, e.g., alumina (AlOₓ), silicon oxide (SiOₓ), or silicon nitride (SiNₓ). An example of silicon oxide (SiOₓ) is silicon dioxide (SiO₂). Preferably, the refractive index of the first passivation layer 41 is greater than that of the second passivation layer 42. The materials used for the first passivation layer 41 and the second passivation layer 42 can be different, or they can be of the same material but with different refractive indices.

In this embodiment, the material used for the first passivation layer 41 is alumina or silicon oxide, and silicon nitride or silicon oxide is used as the material for the second passivation layer 42. Furthermore, silicon nitride can be used for both the first passivation layer 41 and the second passivation layer 42 and, through controlling the manufacturing process, the refractive index of the first passivation layer 41 can be made greater than that of the second passivation layer 42.

The reason for the refractive index of the first passivation layer 41 to be greater than that of the second passivation layer 42 is explained below. To provide more hydrogen atoms to the back surface 22 of the substrate 2, the first passivation layer 41 is designed to have higher refractive index. The first passivation layer 41 with higher refractive index has a loose structure and is likely to be penetrated by a material of the second electrode 62 thereby decreasing the passivation effect of the first passivation layer 41. Therefore, in this embodiment, the second passivation layer 42 is provided and is designed to have a refractive index lower than that of the first passivation layer 41 so that the structure thereof is relatively compact and sense as compared to that of the first passivation layer 41, thereby alleviating the penetration of the material of the second electrode 62 and reducing the influence of the second electrode 62 on the passivation effect provided by the passivation unit 4. Moreover, with the second passivation layer 42, possible contact between the second electrode 62 and the metallic nanoparticles 5 could be prevented so as to maintain the desired effect provided by the metallic nanoparticles 5.

In this embodiment, the metallic nanoparticles 5 capable of reflecting light are disposed in the passivation unit 4 between the first passivation layer 41 and the second passivation layer 42. The metallic nanoparticles 5 can be disposed evenly or can form clusters, where the clusters are then disposed evenly or any other disposition. Alternatively, the metallic nanoparticles 5 can be embedded in the first passivation layer 41 or in the second passivation layer 42. Furthermore, the metallic nanoparticles 5 can be embedded in both the first passivation layer 41 and the second passivation layer 42 at the same time. The metallic nanoparticles 5 are made from gold, gold alloy, silver, or silver alloy.

In this embodiment, the first electrode 61 is disposed on and through the anti-reflective layer 3 and is electrically connected to the emitter layer 23. The second electrode 62 is disposed on and through the passivation unit 4 and touches the back surface 22 of the substrate 2 so as to be electrically connected to the substrate 2. The structures of the first electrode 61 and the second electrode 62 are not limited in this embodiment.

When light is incident on the solar cell 13, the reflection of the light is decreased through the presence of the anti-reflective layer 3 and the roughened structures of the anti-reflective layer 3, the emitter layer 23, and the incident surface 21. The incident light then effectively enters the substrate 2.

When the light enters the substrate 2, the light with shorter wavelength will be absorbed. However, the light with longer wavelength (e.g., greater than 800 nm) and part of the light with shorter wavelength will propagate through the substrate 2 to the back surface 22. When the light passes through the first passivation layer 41 and contacts the metallic nanoparticles 5, plasmonic effect will occur, causing resonance and disturbance of the light. Then, the light will be reflected back to the substrate 2. Due to the different refractive indices of the first passivation layer 41 and the second passivation layer 42, the light will propagate in the substrate 2 in multiple directions. The time for the light to stay inside the solar cell 13 is increased, which results in an increase in the absorption of light. The efficiency of the photovoltaic conversion and the short circuit current of the solar cell 13 are thereby improved.

The metallic nanoparticles 5 are preferred to be disposed in the passivation unit 4 because if the metallic nanoparticles 5 are disposed between the back surface 22 and the first passivation layer 41, the contact area between the back surface 22 and the first passivation layer 41 would be decreased, which might reduce the passivation effect of the passivation unit 4 and increase the surface recombination velocity, thereby reducing the efficiency of the solar cell 13. On the other hand, if the metallic nanoparticles 5 are disposed between the passivation unit 4 and the second electrode 62, the metallic nanoparticles 5 would contact metal in the second electrode 62 and thus lose their function.

From the above explanation, in this embodiment, it is required for the passivation unit 4 to include the first and second passivation layers 41, 42 having different refractive indices, and for the metallic nanoparticles 5 to be disposed in the passivation unit 4. With this structure, the light passing through the first passivation layer 41 would interact with the metallic nanoparticles 5 and plasmonic effect would occur. The plasmonic effect occurs at an interface between a metal and a dielectric material (or vacuum) and the plasmons would interact strongly with light resulting in a polariton. Therefore, the light that passes through the substrate 2 is reflected back to the substrate 2, which increases the time for the light to stay inside the solar cell 13, thereby enhancing the absorption of light and improving the photovoltaic conversion and the short circuit current.

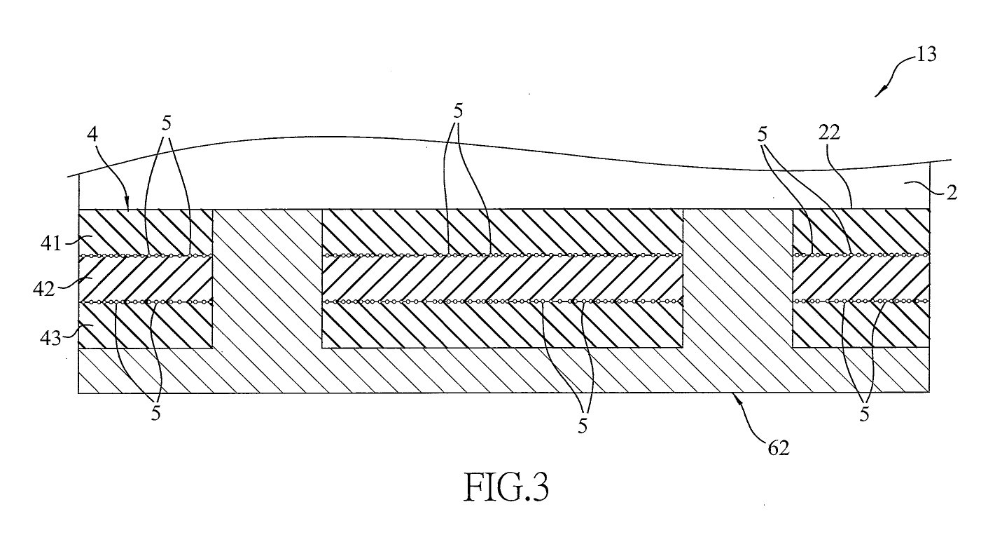

FIG. 3 shows a variant of the solar cell 13 which has a structure similar to that shown in FIG. 2, except that the solar cell 13 of FIG. 3 further includes a third passivation layer 43 that is formed on the second passivation layer 42 opposite to the first passivation layer 41. The second passivation layer 42 has a refractive index greater than that of the third passivation layer 43.

The materials used for the third passivation layer 43 can be alumina, silicon oxide, or silicon nitride. In this embodiment, the material used for the first passivation layer 41 is alumina or silicon oxide. The materials used for the second passivation layer 42 and the third passivation layer 43 are silicon nitride with different refractive indices.

In this variant, the metallic nanoparticles 5 are disposed between the first passivation layer 41 and the second passivation layer 42, and between the second passivation layer 42 and the third passivation layer 43. The metallic nanoparticles 5 can be disposed evenly or can form clusters, where the clusters are then disposed evenly or any other disposition. Alternatively, the metallic nanoparticles 5 can be embedded in at least one of the first passivation layer 41, the second passivation layer 42, and the third passivation layer 43.

With the third passivation layer 43 and the metallic nanoparticles 5 between the second passivation layer 42 and the third passivation layer 43, reflection of light back to the substrate 2 maybe increased, which increases the time for the light to stay inside the solar cell 13, thereby enhancing the photovoltaic conversion and the short circuit current. Moreover, the passivation effect can also be improved.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A solar cell, comprising:
a substrate of a first conductivity type, said substrate having an incident surface and a back surface opposite to said incident surface;
an emitter layer that is formed on said incident surface of said substrate and that has a second conductivity type different from the first conductivity type of said substrate;
an anti-reflective layer formed on said emitter layer opposite to said substrate;
a passivation unit that is formed on said back surface of said substrate;
a plurality of metallic nanoparticles that are capable of reflecting light and that are disposed in said passivation unit;
a first electrode disposed on and electrically connected to said emitter layer; and
a second electrode disposed on said passivation unit and electrically connected to said substrate.

2. The solar cell of claim 1, wherein said metallic nanoparticles are made from a material selected from the group consisting of gold, gold alloy, silver, silver alloy, and combinations thereof.

3. The solar cell of claim 1, wherein said passivation unit includes a first passivation layer formed on said back surface of said substrate and a second passivation layer formed on said first passivation layer opposite to said substrate.

4. The solar cell of claim 3, wherein said first passivation layer has a refractive index greater than that of said second passivation layer.

5. The solar cell of claim 3, wherein said metallic nanoparticles are disposed between said first passivation layer and said second passivation layer.

6. The solar cell of claim 3, wherein said first passivation layer and said second passivation layer are independently made from a material selected from the group consisting of alumina, silicon oxide, silicon nitride, and combinations thereof.

7. The solar cell of claim 3, wherein said passivation unit further includes a third passivation layer formed on said second passivation layer opposite to said first passivation layer.

8. The solar cell of claim 7, wherein said first passivation layer has a refractive index greater than that of said second passivation layer, said second passivation layer having a refractive index greater than that of said third passivation layer.

9. The solar cell of claim 7, wherein said metallic nanoparticles are disposed between said first passivation layer and said second passivation layer and between said second passivation layer and said third passivation layer.

10. The solar cell of claim 7, wherein said first passivation layer, said second passivation layer, and said third passivation layer are independently made from a material selected from the group consisting of alumina, silicon oxide, silicon nitride, and combinations thereof.

11. A solar module, comprising:
a first base plate;
a second base plate;
a solar cell of claim 1 that is disposed between said first base plate and said second base plate; and
an encapsulant that is disposed between said first base plate and said second base plate and that encapsulates said solar cell.
